(19) United States
(12) Patent Application Publication
(10) Pub. No.: US 2025/0379174 A1
(43) Pub. Date: Dec. 11, 2025

(54) ELECTRONIC PACKAGE

(71) Applicant: SILICONWARE PRECISION INDUSTRIES CO., LTD., Taichung City (TW)

(72) Inventors: Chuan-Shun LI, Taichung City (TW); Wen-Yu TENG, Taichung City (TW); Liang-Yi HUNG, Taichung City (TW)

(73) Assignee: SILICONWARE PRECISION INDUSTRIES CO., LTD., Taichung City (TW)

(21) Appl. No.: 18/802,090

(22) Filed: Aug. 13, 2024

(30) Foreign Application Priority Data
Jun. 5, 2024 (TW) 113120888

(51) Int. Cl. H01L 23/00; H01L 23/36; H01L 23/498

(52) U.S. Cl. CPC H01L 24/32; H01L 23/36; H01L 24/29; H01L 23/49822; H01L 24/16; H01L 24/73; H01L 2224/16227; H01L 2224/29034; H01L 2224/29082; H01L 2224/29105; H01L 2224/29109; H01L 2224/32245; H01L 2224/32503; H01L 2224/73253

(57) ABSTRACT

An electronic package is provided, including a carrier structure, an electronic component disposed on the carrier structure, a heat dissipation structure connected to the electronic component through a thermal interface material, a back side metallization disposed on the electronic component and connected to the thermal interface material, and a liquid metal disposed between the thermal interface material and the back side metallization. A surface viscosity of the liquid metal is used to limit the displacement of the thermal interface material relative to the back side metallization, thereby preventing the heat dissipation structure from being poorly bonding to the electronic component due to misalignment of the thermal interface material, which affects the heat dissipation efficiency of the electronic package.

### BACKGROUND

### 1. Technical Field

The present disclosure relates to an electronic package, and more particularly, to an electronic package with a heat dissipation structure.

### 2. Description of Related Art

With the rise and vigorous development of various applications and technologies that require high-speed computing, such as e-sports games, high-resolution audio and video multimedia, and autonomous driving, as well as requirements for miniaturization of related equipment, the number of components contained in semiconductor integrated circuit (IC) employing the package structure such as flip chip ball grid array (FCBGA) is not only increasing day by day, but also the processing and computing speeds are getting faster and faster, causing the heat generated among them to increase significantly, and the requirements for the heat dissipation structure are becoming higher and higher.

FIG. 1 is a schematic cross-section view showing a conventional semiconductor package 1. The semiconductor package 1 includes a package substrate 11, a semiconductor chip 12 mounted on an upper side of the package substrate 11 in a flip-chip manner, and a heat sink 13.

The material of the heat sink 13 is copper, and the material of the semiconductor chip 12 is silicon. In order to improve the bonding effect and the heat dissipation effect between the heat sink 13 and the semiconductor chip 12, a back side metallization (BSM) 15 and a thermal interface material (TIM) 14 are used in the industry to be disposed on a backside of the semiconductor chip 12. Considering that an indium metal sheet has a thermal conductivity of up to 86 W/mK, and its flexibility can withstand the thermal stress generated during the product operation process, the semiconductor industry mostly adopts the indium metal sheet as the thermal interface material 14.

Furthermore, with the demand for thin and light products, the thickness and weight of the indium metal sheet are also constantly decreasing, leading to new challenges for packaging technology. For instance, in order to prevent the thin and light indium metal sheet from not being perfectly aligned with the position of the semiconductor chip 12 or even from being blown away from a product surface by the airflow of the production line duct during packaging operations at this stage, a layer of adhesive 16 is applied between the TIM 14 and the BSM 15 to fix them.

However, the semiconductor package warps during a reliability thermal cycle test, and no matter how much the amount of adhesive is controlled, the adhesive would be squeezed into the inner edge of the indium metal sheet, resulting in incomplete volatilization. In addition, the adhesive is composed of polymer material and forms an obstacle when the indium metal sheet is bonded to the back side metallization, which not only results in incomplete bonding, but also causes the loss of the heat dissipation performance.

Therefore, how to overcome the aforementioned problems of conventional techniques has become an urgent issue to be solved.

### SUMMARY

In view of the aforementioned shortcomings of the prior art, the present disclosure provides an electronic package, which comprises: an electronic component disposed on the carrier structure; a heat dissipation structure disposed on the electronic component; a thermal interface material provided for the heat dissipation structure to be connected on the electronic component through the thermal interface material; a back side metallization disposed on the electronic component and connected to the thermal interface material; and a liquid metal provided between the thermal interface material and the back side metallization, and bonded to the thermal interface material.

In the aforementioned electronic package, the electronic component has an active surface and a non-active surface opposite to each other, and the active surface is electrically connected to the carrier structure through a plurality of conductive bumps in a flip-chip manner.

In the aforementioned electronic package, the heat dissipation structure has a top sheet and a supporting leg, one end of the supporting leg is bonded to the top sheet, and another end of the supporting leg is disposed on the carrier structure, and a bottom of the top sheet is opposite to a top of the electronic component.

In the aforementioned electronic package, the thermal interface material is a liquid metal, a metal layer, or a thermally conductive colloid.

In the aforementioned electronic package, the thermal interface material is an indium metal layer.

In the aforementioned electronic package, the back side metallization comprises at least one of an aluminum layer, a titanium layer, a chromium layer, a nickel layer, a nickel-vanadium alloy layer, and a copper layer.

In the aforementioned electronic package, the liquid metal comprises gallium metal particles.

In the aforementioned electronic package, the liquid metal serves as a fixing material between the thermal interface material and the back side metallization, and is melted into the thermal interface material at a high temperature.

In the aforementioned electronic package, the liquid metal has a viscosity to limit a displacement of the thermal interface material relative to the back side metallization.

In the aforementioned electronic package, a distribution area of the liquid metal occupies at most 1% of a distribution area of the back side metallization.

In the aforementioned electronic package, the liquid metal is melted into the thermal interface metal to form a plurality of metal particles. For instance, the metal particles have a first thermal conductivity coefficient, the thermal interface material has a second thermal conductivity coefficient, and the first thermal conductivity coefficient is less than the second thermal conductivity coefficient.

In the aforementioned electronic package, the liquid metal is correspondingly located at a center position of the electronic component, and the metal particles are correspondingly distributed on the center position of the electronic component after heating and pressurization. Alternatively, the liquid metal is correspondingly provided around the electronic component, and the metal particles are correspondingly distributed around the electronic component after heating and pressurization.

By the implementation of the present disclosure, the liquid metal is mainly provided between the thermal interface material and the back side metallization, and since the liquid metal has viscosity to limit the displacement of the thermal interface material relative to the back side metallization, thereby preventing the poor bonding between the heat dissipation structure and the electronic component due to the misalignment of the thermal interface material in subsequent processes, resulting in affecting the heat dissipation efficiency of the electronic package. In addition, the liquid metal can be melted into the thermal interface material at a high temperature, which not only does not affect the connection between the thermal interface material and the back side metallization, but also can adhere closely to the surface of the electronic component, thereby improving the heat dissipation efficiency of the electronic package.

### BRIEF DESCRIPTION OF THE DRAWINGS

FIG. 1 is a schematic cross-section view showing a conventional semiconductor package.

FIG. 2 and FIG. 3 are schematic cross-section views showing an electronic package according to the present disclosure.

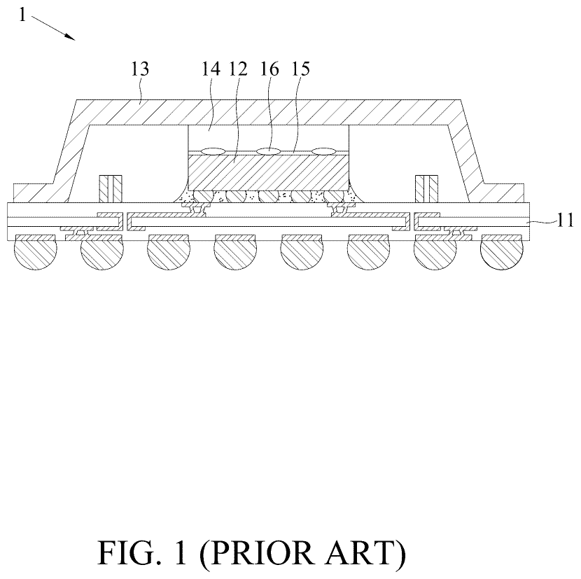

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a” “one,” and the like are merely for clear explanation rather than limiting the practicable scope of the present disclosure, and thus, alterations or adjustments of the relative relationships thereof without essentially altering the technical contents should still be considered in the practicable scope of the present disclosure.

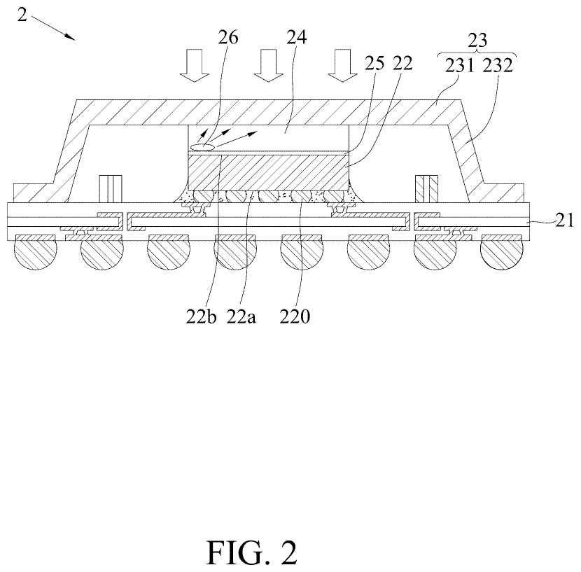

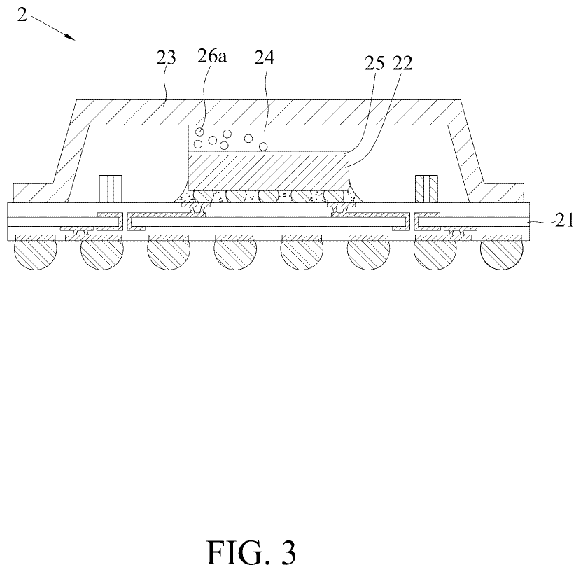

FIG. 2 and FIG. 3 are schematic cross-section views showing an electronic package 2 according to the present disclosure. The electronic package 2 comprises: a carrier structure 21; an electronic component 22 disposed on the carrier structure 21 and electrically connected to the carrier structure 21; a heat dissipation structure 23 disposed on the electronic component;

a thermal interface material (TIM) 24 provided for the heat dissipation structure 23 to be connected on the electronic component 22 through the thermal interface material 24; a back side metallization 25 disposed on the electronic component 22 and connected to the thermal interface material 24; and a liquid metal 26 provided between the thermal interface material 24 and the back side metallization 25, and bonded to the thermal interface material 24.

The aforementioned carrier structure 21 is, for example, a packaging substrate with a core layer and a circuit structure, or a coreless circuit structure, in which a circuit layer, such as a redistribution layer (RDL), is formed on a dielectric material. The circuit layer may also be a lead frame, a silicon interposer, a wafer, or other boards with metal routing, etc., and is not limited to the above.

The aforementioned electronic component 22 is connected to the carrier structure 21 and electrically connected to the circuit layer. The electronic component 22 may be an active component, a passive component, a package structure, or a combination thereof. The active component may be an application processor (AP) used in mobile devices such as mobile phones or other semiconductor chips such as a computing chip, while the passive component is, for example, a resistor, a capacitor, or an inductor, etc. In one embodiment, the electronic component 22 is a semiconductor chip having an active surface 22a and a non-active surface 22b opposing each other, and the active surface 22a is electrically connected to the carrier structure 21 via a plurality of conductive bumps 220 in a flip-chip manner.

The aforementioned heat dissipation structure 23 is, for example, a heat sink, a heat lid, or other components or structures with equivalent functions. In one embodiment, the heat dissipation structure 23 has a top sheet 231 and supporting legs 232, wherein one end of the supporting leg 232 is bonded to the top sheet 231, and the other end of the supporting leg 232 is disposed on the carrier structure 21, for a bottom of the top sheet 231 to be opposite a top of the electronic component 22. In addition, the material for the heat dissipation structure 23 is copper metal.

A thermal interface material 24 is further provided between the top of the aforementioned electronic component 22 and the bottom of the top sheet 231 of the heat dissipation structure 23, for transferring the heat generated by the electronic component 22 to the heat dissipation structure 23 and then dissipating it to the environment. The thermal interface material 24 is, for example, a liquid metal, a metal layer, or a thermally conductive colloid. In one embodiment, the thermal interface material 24 is, for example, an indium metal layer.

The back side metallization 25 is disposed on the electronic component 22 and connected to the thermal interface material 24. The back side metallization 25 may be a multi-layer metal layer structure, for example, including at least one of an aluminum layer, a titanium layer, a chromium layer, a nickel layer, a nickel-vanadium alloy layer and a copper layer.

The liquid metal 26 is provided between the thermal interface material 24 and the back side metallization 25, and is combined with the thermal interface material 24. In one embodiment, the liquid metal 26 comprises gallium metal particles.

The liquid metal 26 serves as a fixing material between the thermal interface material 24 and the back side metallization 25, and is melted into the thermal interface material 24 (e.g., indium metal layer) at a high temperature, which not only does not affect the connection between the thermal interface material 24 and the back side metallization 25, but also can closely adhere to the surface of the electronic component 22.

In one embodiment, the liquid metal 26 is first provided between the thermal interface material 24 and the back side metallization 25, and a pressurization and heating manufacturing process is performed (as shown in FIG. 2), so that the thermal interface material 24 is liquefied, and that the liquid metal 26 is melted into the thermal interface metal 24 to form a plurality of metal particles 26a (as shown in FIG. 3).

In one embodiment, the metal particle 26a has a first thermal conductivity coefficient, the thermal interface material 24 has a second thermal conductivity coefficient, and the first thermal conductivity coefficient is less than the second thermal conductivity coefficient.

In one embodiment, the distribution area of the liquid metal 26 occupies at most 1% (preferably 0.5%) of the distribution area of the back side metallization 25. Furthermore, if the liquid metal 26 is located correspondingly to a center position of the electronic component 22, the metal particles 26a are distributed correspondingly to the center position of the electronic component 22 after heating and pressurization; and if the liquid metal 26 is provided correspondingly around the electronic component 22, the metal particles 26a are distributed correspondingly around the electronic component 22 after heating and pressurization.

To sum up, the electronic package of the present disclosure mainly provides the liquid metal between the thermal interface material and the back side metallization, and since the liquid metal has viscosity to limit the displacement of the thermal interface material relative to the back side metallization, thereby preventing the poor bonding between the heat dissipation structure and the electronic component due to the misalignment of the thermal interface material in subsequent processes, resulting in affecting the heat dissipation efficiency of the electronic package. In addition, the liquid metal can be melted into the thermal interface material at a high temperature, which not only does not affect the connection between the thermal interface material and the back side metallization, but also can adhere closely to the surface of the electronic component, thereby improving the heat dissipation efficiency of the electronic package.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a carrier structure;
an electronic component disposed on the carrier structure;
a heat dissipation structure disposed on the electronic component;
a thermal interface material provided for the heat dissipation structure to be disposed on the electronic component through the thermal interface material;
a back side metallization disposed on the electronic component and connected to the thermal interface material; and
a liquid metal provided between the thermal interface material and the back side metallization, and bonded to the thermal interface material.

2. The electronic package of claim 1, wherein the electronic component has an active surface and a non-active surface opposite to each other, and the active surface is electrically connected to the carrier structure through a plurality of conductive bumps in a flip-chip manner.

3. The electronic package of claim 1, wherein the heat dissipation structure has a top sheet and a supporting leg, one end of the supporting leg is bonded to the top sheet, and another end of the supporting leg is disposed on the carrier structure, and a bottom of the top sheet is opposite to a top of the electronic component.

4. The electronic package of claim 1, wherein the thermal interface material is a liquid metal, a metal layer, or a thermally conductive colloid.

5. The electronic package of claim 1, wherein the thermal interface material is an indium metal layer.

6. The electronic package of claim 1, wherein the back side metallization comprises at least one of an aluminum layer, a titanium layer, a chromium layer, a nickel layer, a nickel-vanadium alloy layer, and a copper layer.

7. The electronic package of claim 1, wherein the liquid metal comprises gallium metal particles.

8. The electronic package of claim 1, wherein the liquid metal serves as a fixing material between the thermal interface material and the back side metallization, and is melted into the thermal interface material at a high temperature.

9. The electronic package of claim 1, wherein the liquid metal has a viscosity to limit a displacement of the thermal interface material relative to the back side metallization.

10. The electronic package of claim 1, wherein a distribution area of the liquid metal occupies at most 1% of a distribution area of the back side metallization.

11. The electronic package of claim 1, wherein the liquid metal is melted into the thermal interface metal to form a plurality of metal particles.

12. The electronic package of claim 11, wherein the metal particles have a first thermal conductivity coefficient, the thermal interface material has a second thermal conductivity coefficient, and the first thermal conductivity coefficient is less than the second thermal conductivity coefficient.

13. The electronic package of claim 11, wherein the liquid metal is correspondingly located at a center position of the electronic component, and the metal particles are correspondingly distributed on the center position of the electronic component after heating and pressurization.

14. The electronic package of claim 11, wherein the liquid metal is correspondingly provided around the electronic component, and the metal particles are correspondingly distributed around the electronic component after heating and pressurization.
